(19) United States
(12) Patent Application Publication
(10) Pub. No.: US 2013/0327562 A1
(43) Pub. Date: Dec. 12, 2013

(54) TOUCH PANEL

(71) Applicant: SAMSUNG ELECTRO-MECHANICS CO., LTD., Suwon (KR)

(72) Inventors: Chung Mo Yang, Suwon (KR); Jung Ryoul Yim, Suwon (KR); Sang Su Hong, Suwon (KR)

(21) Appl. No.: 13/908,888

(22) Filed: Jun. 3, 2013

(30) Foreign Application Priority Data
Jun. 8, 2012 (KR) 10-2012-0061732

(51) Int. Cl. H05K 1/09

(52) U.S. Cl. CPC H05K 1/09
USPC 174/255

(57) ABSTRACT

Disclosed herein is a touch panel. A touch panel 100 according to a preferred embodiment of the present invention is configured to include a transparent substrate 110 and an electrode 120 formed of conductive non-oxide ceramics on the transparent substrate 110. The electrode 120 is formed of conductive non-oxide ceramics (Ti₃SiC₂) and an additional black oxide treatment is not required, thereby improving productivity of the touch panel 100.

### CROSS REFERENCE TO RELATED APPLICATION

This application claims the benefit of Korean Patent Application No. 10-2012-0061732, filed on Jun. 8, 2012, entitled “Touch Panel”, which is hereby incorporated by reference in its entirety into this application.

### BACKGROUND OF THE INVENTION

1. Technical Field

The present invention relates to a touch panel.

2. Description of the Related Art

In accordance with the growth of computers using a digital technology, devices assisting computers have also been developed, and personal computers, portable transmitters and other personal information processors execute processing of text and graphics using a variety of input devices such as a keyboard and a mouse.

While the rapid advancement of an information-oriented society has widened the use of computers more and more, it is difficult to efficiently operate products using only a keyboard and a mouse currently serving as an input device. Therefore, the necessity for a device that is simple, has minimum malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

This touch panel is mounted on a display surface of a flat panel display device such as an electronic organizer, a liquid crystal display (LCD) device, a plasma display panel (PDP), an electroluminescence (El) element, or the like, and an image display device like a cathode ray tube (CRT), and is used to allow users to select desired information while viewing the image display device.

In addition, the touch panel is classified into a resistive type touch panel, a capacitive type touch panel, an electromagnetic type touch panel, a surface acoustic wave (SAW) type touch panel, and an infrared type touch panel. These various types of touch panels are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch panel and the capacitive type touch panel have been prominently used in a wide range of fields. Such touch panels normally use an electrode made with Indium Tin Oxide (ITO). ITO has excellent electric conductivity; however its raw material, Indium, is expensive as a rare earth metal which is expected to be depleted within 10 years, so that a demand and supply thereof is not smooth.

For these reasons, as described in Korean Patent Laid-Open Publication No. 10-2010-0091497, forming an electrode using metals has been actively studied. Accordingly, when an electrode is formed of metals, it has much better electric conductivity than ITO and a demand and supply thereof is smooth; however, visibility may be degraded due to peculiar luster of metals. In order to solve the above problems, a black oxide treatment which disposes metal oxide on upper/lower surfaces of an electrode formed of metals has been performed, but it causes productivity to be deteriorated because of a complicated manufacturing process.

### SUMMARY OF THE INVENTION

The present invention has-been made in an effort to provide a touch panel in which an electrode is formed of conductive non-oxide ceramics (Ti₃SiC₂) and an additional black oxide treatment is not required.

According to a preferred embodiment of the present invention, there is provided a touch panel, including: a transparent substrate; and an electrode which is formed of conductive non-oxide ceramics on the transparent substrate and senses a touch.

The conductive non-oxide ceramic may be Ti₃SiC₂.

Sheet resistance of the electrode may be 1 Ω/□ or below.

Sheet resistance of the electrode may be 0.15 Ω/□ or below.

A L* value of a L*a*b* color system of the electrode may be 50.00 or more.

The electrode may be formed by deposition process using a sputter.

Carbon may be supplied during the deposition process.

The touch panel may further include a wiring formed at edges of the electrodes.

The wiring and the electrode may be integrally formed.

The wiring may be formed of conductive non-oxide ceramics.

The conductive non-oxide ceramics may be Ti₃SiC₂.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a plan view of a touch panel according to a preferred embodiment of the present invention;

FIG. 2 is a cross-sectional view of a touch panel according to the preferred embodiment of the present invention;

FIG. 3 is a cross-sectional view depicting a process of measuring an electrode of the touch panel illustrated in FIG. 1 from a lower side;

FIG. 4 is a cross-sectional view depicting a process of measuring the electrode of the touch panel illustrated in FIG. 1 from an upper side;

FIGS. 5 to 8 are cross-sectional views of a touch panel manufactured using the preferred embodiment of the present invention; and

FIG. 9 is a drawing depicting a unit cell of Ti₃SiC₂.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the accompanying drawings.

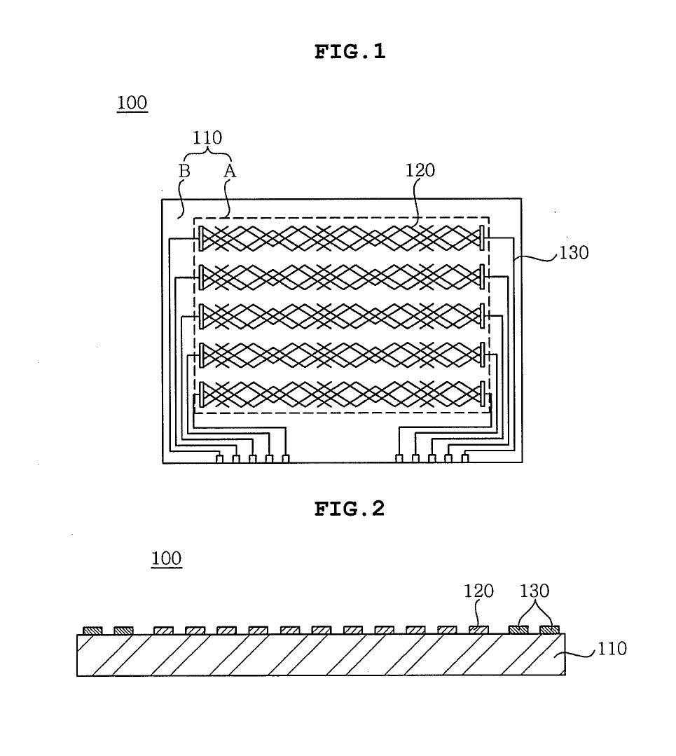

FIG. 1 is a plan view of a touch panel according to a preferred embodiment of the present invention, and FIG. 2 is a cross-sectional diagram of the touch panel according to the preferred embodiment of the present invention.

As illustrated in FIGS. 1 and 2, a touch panel 100 according to the preferred embodiment of the present invention is configured to include a transparent substrate 110 and an electrode 120 formed of conductive non-oxide ceramics on the transparent substrate 110 and sensing a touch.

The transparent substrate 110 serves to provide a region where the electrode 120 and a wire 130 are formed. Here, the transparent substrate 110 is divided into an active area A and a bezel area B. The active area A, an area where the electrode 120 is formed to recognize a touch of an input means, is disposed at a center of the transparent substrate 110, and a bezel area B, an area where the wire 130 applying electricity to the electrode 120 is formed, is disposed at a border of the active area A. Here, the transparent substrate 110 should have support force, which may support the electrode 120 and the wire 130, and transparency to allow users to recognize an image provided on an image display device. In consideration of said support force and transparency, the transparent substrate 110 is made of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), glass, or tempered glass; however it is not restricted thereto.

On the other hand, the transparent substrate 110 may be a window equipped at a most outward of the touch panel 100. Accordingly, when the transparent substrate 110 is a window, the electrode 120 is formed directly in a window. Therefore, a process of forming the electrode 120 on an additional transparent substrate 110 and then attaching it to the window may be omitted, thereby making it possible to simplify a manufacturing process and reduce the overall thickness of the touch panel 100.

Meanwhile, a high frequency treatment or a primer treatment may be performed to activate the transparent substrate 110. Accordingly, by activating the transparent substrate 110, adhesive force between the transparent substrate 110 and the electrode 120 may be improved.

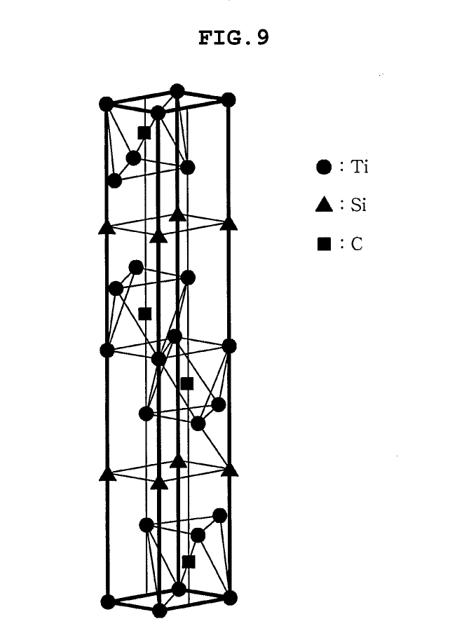

The electrode 120 serves to allow a controller to recognize touched coordinates by sensing a touch of a user. Here, the electrode 120 is formed of conductive non-oxide ceramics, and the conductive non-oxide ceramics may be Ti₃SiC₂. FIG. 9 is a drawing depicting a unit cell of Ti₃SiC₂, and phases of Ti₃SiC₂ are disposed on a layer of TiCₓ between pure layers of Si as illustrated in FIG. 9. On the other hand, the electrode 120 may be formed by a deposition process using a sputter. In addition, carbon may be supplied during the vapor process. To be used as the electrode 120 of the touch panel 100, sheet resistance of the electrode 120 may be 1 Ω/□ or below, preferably 0.15 Ω/□ or below. Actually, sheet resistance of the electrode 120 is measured at 0.12 Ω/□ on average as a result of forming the electrode 120 with sputter using Ti₃SiC₂, which is good to be used as the electrode 120 of the touch panel 100. However, the electrode 120 does not need to be formed of Ti₃SiC₂, but may be formed using all conductive non-oxide ceramics known to those skilled in the art.

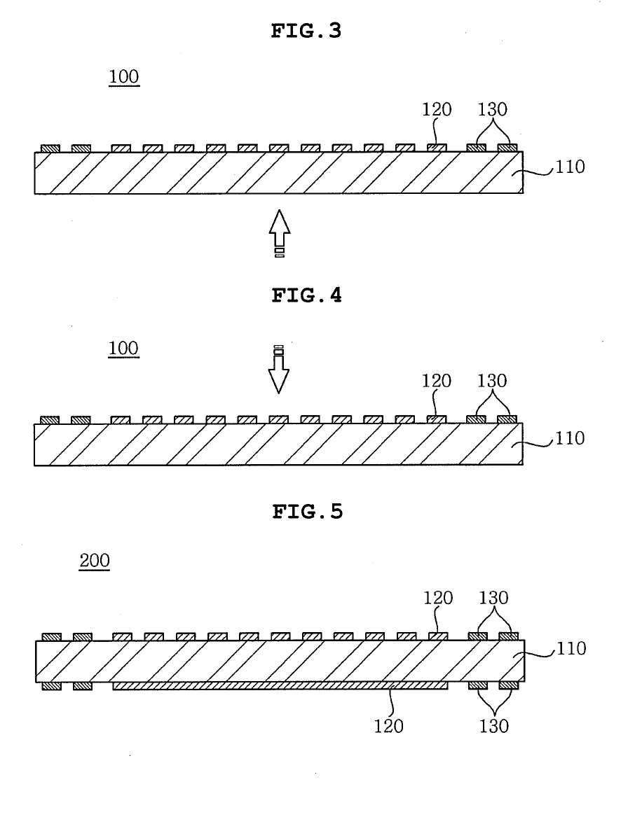

In addition, after forming the electrode 120 using Ti₃SiC₂, the L*a*b* color system of the electrode 120 is like following Tables 1 and 2. For reference, Table 1 shows measured values of a lower side of the electrode 120 as illustrated in FIG. 3 (refer to an arrow), and Table 2 shows measured values of an upper side of the electrode 120 as illustrated in FIG. 4 (refer to an arrow).

TABLE 1

| SCI | L* | a* | b* | ΔEab* | C*ab |
|---|---|---|---|---|---|
| Measured value 1 | 56.24 | 1.53 | 0.28 | 56.17 | 1.56 |
| Measured value 2 | 56.06 | 1.52 | 0.29 | 55.99 | 1.55 |
| Measured value 3 | 55.94 | 1.50 | 0.30 | 55.87 | 1.53 |
| Average value | 56.08 | 1.52 | 0.29 | 56.01 | 1.54 |

TABLE 2

| SCI | L* | a* | b* | ΔEab* | C*ab |
|---|---|---|---|---|---|
| Measured value 1 | 50.60 | 0.66 | 3.64 | 50.65 | 3.70 |
| Measured value 2 | 50.71 | 0.65 | 3.64 | 50.75 | 3.70 |
| Measured value 3 | 50.79 | 0.67 | 3.64 | 50.83 | 3.70 |
| Average value | 50.70 | 0.66 | 3.64 | 50.75 | 3.70 |

As shown in Table 1 and Table 2, the electrode 120 has L* values of 50.00 or more based on the L*a*b* color system. Here, the L* value indicates brightness. As it goes higher, it gets closer to black. The L* values of the electrode 120 are 50.00 or more and relatively high. As described above, since the L* values of the electrode 120 are high, it may prevent light from being reflected from the electrode 120 and it may, accordingly, improve visibility of the touch panel 100. Moreover, an additional black oxide treatment is not required, thereby improving productivity of the touch panel 100.

On the other hand, the electrode 120 may be formed in a Mesh pattern having a width in micrometers (μm) so as not to be visually recognized by a user. In addition, the electrode 120 may be formed in a stick pattern as illustrated (refer to FIG. 1), but it is not restricted thereto. The electrode 120 may also be formed in a diamond pattern, a quadrangular pattern, a triangular pattern, a circular pattern, and may also be formed in a conductive film type which is not a pattern.

Additionally, the wiring 130 receiving an electrical signal from the electrode 120 is formed at edges of the electrode 120. Here, the wiring 130 may be formed integrally with the electrode 120 by using conductive non-oxide ceramics like Ti₃SiC₂. Accordingly, forming the wiring 130 and the electrode 120 integrally may simplify a manufacturing process and shorten a lead time. Besides, a bonding process between the wiring 130 and the electrode 120 may be abbreviated, thereby preventing a problem of stepped pulley occurrence or bonding defects between the wiring 130 and the electrode 120.

As illustrated in FIG. 2, in case of the touch panel 100 according to the preferred embodiment of the present invention, a capacitive type touch panel may be manufactured using the electrode 120 of a layer pattern. However, a touch panel according to the present invention is not restricted thereto and various types of touch panels including the pattern may be manufactured as described later.

FIGS. 5 to 8 are cross-sectional diagrams of a touch panel using the preferred embodiments of the present invention.

As illustrated in FIG. 5, a capacitive type touch panel 200 (refer to FIG. 5) may be manufactured by forming the electrode 120 on both sides of the transparent substrate 110 as illustrated in FIG. 5.

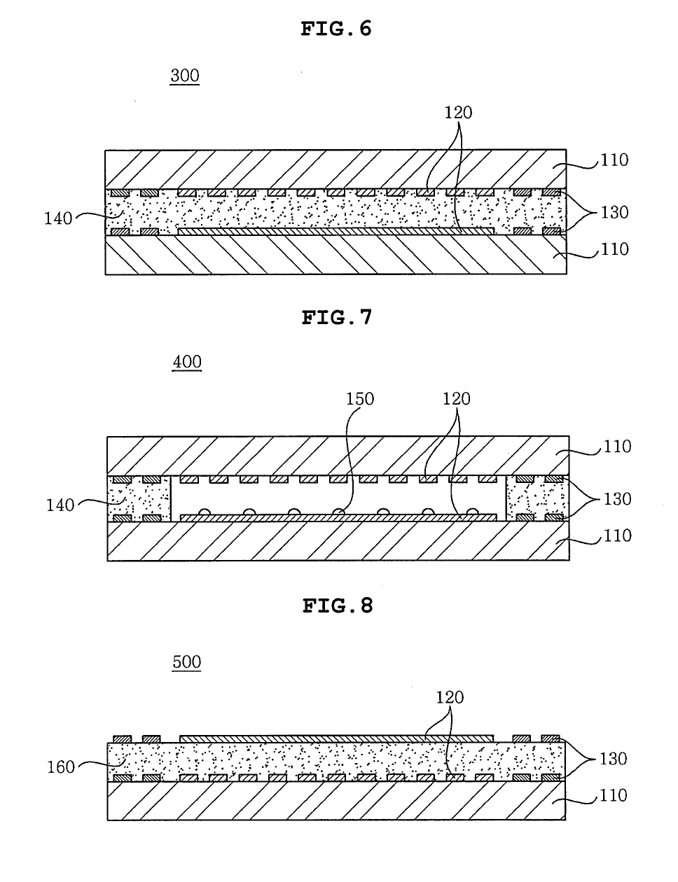

In addition, as illustrated in FIGS. 6 and 7, a capacitive type touch panel 300 (refer to FIG. 6) or a resistive type touch panel 400 (refer to FIG. 7) may be manufactured by providing two transparent substrates 110, which have the electrode 120 formed on one surface thereof, and bonding two transparent substrates 110 to an adhesive layer 140 so that the electrodes 120 formed thereon may face each other. Here, in case of a capacitive type touch panel 300 (refer to FIG. 6), the adhesive layer 140 is attached to a front surface of the transparent substrate 110 so as to insulate the two facing electrodes 120 from each other. On the other hand, in the case of the resistive type touch panel 400 (refer to FIG. 7), when pressure of an input unit is applied, the adhesive layer 140 is attached only to the edges of the transparent substrate 110 so as to bond the two facing electrodes 120 to each other and when the pressure of the input unit is removed, a dot spacer 150 providing repulsive force to return the electrode 120 to an original position is provided on exposed surfaces of the electrode 120.

Meanwhile, as illustrated in FIG. 8, a capacitive type touch panel 500 (refer to FIG. 8) may be manufactured by forming the electrode 120 on the transparent substrate 110, forming an insulating layer 160 thereon, and again forming the electrode 120 thereon. Here, the insulating layer 160 may be formed of epoxy, acrylic-based resin, a SiOx thin film, a SiNx thin film, and the like.

In touch panels 200, 300, 400, and 500 modified according to the preferred embodiment of the present invention, the electrode 120 is also formed of conductive non-oxide ceramics (Ti₃SiC₂) and thus an additional black oxide treatment is not required, thereby making it possible to improve visibility of the touch panels 200, 300, 400 and 500. Moreover, an additional black oxide treatment is not required, thereby making it possible to productivity of the touch panels 200, 300, 400 and 500.

With a touch panel according to the present invention, an electrode is formed of conductive non-oxide ceramics (Ti₃SiC₂) and an additional black oxide treatment is not required, thereby making it possible to improve productivity of the touch panel.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel, comprising:
a transparent substrate; and
an electrode formed of conductive non-oxide ceramics on the transparent substrate and sensing a touch.

2. The touch panel as set forth in claim 1, wherein the conductive non-oxide ceramics is Ti₃SiC₂.

3. The touch panel as set forth in claim 1, wherein sheet resistance of the electrode is 1 Ω/□ or below.

4. The touch panel as set forth in claim 1, wherein the sheet resistance of the electrode is 0.15 Ω/□ or below.

5. The touch panel as set forth in claim 1, wherein a L* value of L*a*b* color system of the electrode is 50.00 or more.

6. The touch panel as set forth in claim 1, wherein the electrode is formed by a deposition process using a sputter.

7. The touch panel as set forth in claim 6, wherein carbon is supplied during the deposition process.

8. The touch panel as set forth in claim 1, further comprising a wiring formed at the edges of the electrode.

9. The touch panel as set forth in claim 8, wherein the wiring and the electrode are integrally formed.

10. The touch panel as set forth in claim 8, wherein the wiring is formed of conductive non-oxide ceramics.

11. The touch panel as set forth in claim 9, wherein the conductive non-oxide ceramics is Ti₃SiC₂.
